(19) United States
(12) Patent Application Publication
(10) Pub. No.: US 2007/0264810 A1
(43) Pub. Date: Nov. 15, 2007

(54) Semiconductor devices and methods of forming the same

(76) Inventors: Ki-Chul Kim, Suwon-si (KR); Hwa-Sung Rhee, Seongnam-si (KR); Sug-Hyun Sung, Suwon-si (KR); Sang-Doo Kim, Seoul (KR)

Correspondence Address: LEE & MORSE, P.C., 3141 FAIRVIEW PARK DRIVE, SUITE 500, FALLS CHURCH, VA, 22042, US

(21) Appl. No.: 11/783,181

(22) Filed: Apr. 6, 2007

(30) Foreign Application Priority Data
May 10, 2006 (KR) 10-2006-0042076

(51) Int. Cl. H01L 21/3205; H01L 21/4763

(52) U.S. Cl. 438/585; 438/592

(57) ABSTRACT

A semiconductor device and a method of manufacturing the same, including obtaining a semiconductor substrate, forming a device isolating layer having a depression part and a protrusion part in the semiconductor substrate, forming a gate insulating layer and a gate electrode on the semiconductor substrate, forming a spacer in communication with the gate electrode, removing a portion of the semiconductor substrate to form at least one substrate recess region in an upper surface of the semiconductor substrate and at least one substrate remaining portion extending to a same height as the semiconductor substrate, so that the substrate remaining portion forms a sidewall of the substrate recess region and is in communication with the device isolating layer, and forming a substrate epitaxial layer in the substrate recess region.

### BACKGROUND OF THE INVENTION

1. Field of the Invention

The present invention relates to semiconductor devices and methods of forming the same. In particular, the present invention relates to an improved method of forming a semiconductor device having reduced junction leakage current.

2. Description of the Related Art

In general, as the integration level of semiconductor devices increases, attempts are made to increase carrier mobility in channel regions of the semiconductor devices, e.g., by using strain.

For example, one conventional method employing strain may include formation of recess regions in a silicon substrate on both sides of a gate electrode, followed by formation of an epitaxial layer in the recess regions to operate as a source/drain. The difference in lattice constants between the silicon substrate and the material employed for forming the epitaxial layer may generate a horizontal compressive strain and, thereby, form a compressive strained layer in a channel region of the semiconductor device.

Conventional formation of recess regions in a silicon substrate may include removing portions of silicon substrate in areas adjacent to a device isolating layer or a spacer of a gate electrode to expose a sidewall thereof, growing an epitaxial layer in the formed recess regions, and forming a silicide region on the epitaxial layer.

However, epitaxial growth adjacent to insulating materials may trigger lattice defects in the epitaxial layer, e.g., a gap or a void may occur between the epitaxial layer and the adjacent element, i.e., device isolation region and/or spacer. Therefore, upon formation of a silicide layer on the epitaxial layer, the silicide layer may be formed between the epitaxial layer and the adjacent element, i.e., device isolation layer and/or spacer, thereby triggering a junction leakage current between a source/drain region and a well region.

Accordingly, there exists a need for an improved method of manufacturing a semiconductor device exhibiting minimized junction leakage current.

### SUMMARY OF THE INVENTION

The present invention is therefore directed to a semiconductor device and a method of forming the same, which substantially overcome one or more of the problems due to the limitations and disadvantages of the related art.

It is therefore a feature of an embodiment of the present invention to provide a semiconductor device having minimized junction leakage current.

It is another feature of an embodiment of the present invention to provide a method for forming a highly integrated semiconductor device capable of minimizing junction leakage current.

At least one of the above and other features of the present invention may be realized by providing a method of manufacturing a semiconductor device, including obtaining a semiconductor substrate, forming a device isolating layer having a depression part and a protrusion part in the semiconductor substrate, forming a gate insulating layer and a gate electrode on the semiconductor substrate, forming a spacer in communication with the gate electrode, removing a portion of the semiconductor substrate to form at least one substrate recess region in an upper surface of the semiconductor substrate and at least one substrate remaining portion extending to a same height as the semiconductor substrate, so that the substrate remaining portion forms a sidewall of the substrate recess region and is in communication with the device isolating layer, and forming a substrate epitaxial layer in the substrate recess region. Forming the substrate epitaxial layer may include forming a silicon germanium epitaxial layer.

Forming the substrate remaining portion may include performing anisotropic dry etching process. Performing the anisotropic dry etching process may include directing an etch gas in a direction forming a first angle with a sidewall of the protrusion part of the device isolating layer. Forming the first angle with a sidewall of the protrusion part of the device isolating layer may include forming an acute angle. An upper surface of the substrate remaining portion may be formed to have a width of at least about 50 angstroms. Additionally, forming the substrate remaining portion may include forming a mask pattern on the device isolating layer and the semiconductor substrate adjacent to the device isolating layer, anisotropically etching the semiconductor substrate by using the mask pattern as an etch mask, and removing the mask pattern.

Forming the substrate remaining portion may include performing an etch process by supplying about 300-700 sccm of hydrogen bromide (HBr) gas, about 100-500 sccm of helium (He) gas and about 5-15 sccm of O₂ gas, with a source power of about 300-500 W and back-bias power of about 1-100 W, under a temperature of about 20-60° C. and a pressure of about 20-50 mTorr. Forming the substrate remaining portion may further include removing an oxide layer before etching, by supplying about 50-120 sccm of carbon tetrafluoride (CF₄) gas, and supplying a source power of about 500-700 W with a back-bias power of about 1-150 W for about 5-10 seconds, under a temperature of about 20-60° C. and a pressure of about 5-10 mTorr.

The method may further include forming a metal silicide layer on the substrate epitaxial layer. Also, the method may include forming a capping layer pattern on the gate electrode. Additionally, the method may include removing a portion of the gate electrode to form at least one gate recess region and a gate remaining portion and forming a gate epitaxial layer in the gate recess region. Forming the gate epitaxial layer may include forming a silicon germanium epitaxial layer.

In another aspect of the present invention, there is provided a semiconductor device, including a semiconductor substrate, a device isolating layer on the semiconductor substrate, the device isolating layer including a depression part in the semiconductor substrate and a protrusion part projecting upward from the semiconductor substrate, a gate electrode on the semiconductor substrate, a spacer on the semiconductor substrate and in communication with the gate electrode, at least one substrate recess region in the semiconductor substrate, a substrate remaining portion in communication with the device isolating layer and the substrate recess region, the substrate remaining portion having a substantially same height level as an upper surface of the semiconductor substrate, and a substrate epitaxial layer in the substrate recess region. An upper surface of the substrate remaining portion may have a width of at least about 50 angstroms.

The semiconductor device may further include at least one gate recess region in the gate electrode, a gate remaining portion in communication with the spacer, and a gate epitaxial layer in the gate recess region. The substrate epitaxial layer and the gate epitaxial layer may include a silicon germanium epitaxial layer. Additionally, the semiconductor device may further include a capping layer pattern on the gate electrode. The semiconductor device may also include a silicide metal layer on the epitaxial layer.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1-2A and 3-4 illustrate cross-sectional views of sequential steps in a method of forming a semiconductor device according to an embodiment of the present invention;

FIG. 2B illustrates an enlarged view of part A illustrated in FIG. 2A; and

FIG. 5 illustrates a cross-sectional view of a semiconductor device formed according to another embodiment of the present invention.

### DETAILED DESCRIPTION OF THE INVENTION

Korean Patent Application No. 10-2006-0042076, filed on May 10, 2006, in the Korean Intellectual Property Office, and entitled: “Semiconductor Devices and Methods of Forming the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

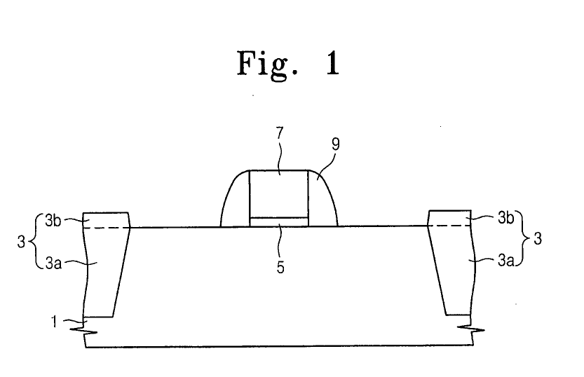

An exemplary embodiment of a method of forming a semiconductor device according to the present invention will now be more fully described in conjunction with FIGS. 1-4.

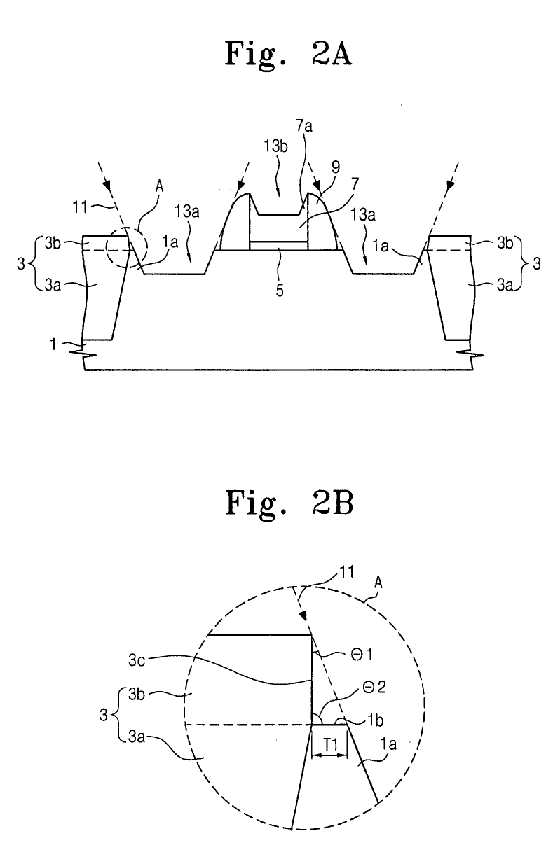

First, as illustrated in FIG. 1, a device isolating layer 3 may be formed of an insulating material, e.g., silicon nitride, silicon oxide, and so forth, on a semiconductor substrate 1, e.g., a silicon substrate, via a Shallow Trench Isolation (STI) method to define an active region. The device isolating layer 3 may include a depression part 3a and a protrusion part 3b. The depression part 3a may be formed in the semiconductor substrate 1, and the protrusion part 3b may be in communication with the depression part 3a and project upward from the semiconductor substrate 1 at a predetermined angle, so that a sidewall 3c, as illustrated in FIG. 2B, of the protrusion part 3b may form the predetermined angle with the semiconductor substrate, as will be discussed in more detail below with respect to FIGS. 2A-2B.

Next, as further illustrated in FIG. 1, a gate insulating layer 5 and a gate electrode 7 may be formed sequentially on the semiconductor substrate 1. The gate insulating layer 5 may be formed on the semiconductor substrate 1 of thermal oxide. The gate electrode 7 may be formed on the gate insulating layer 5 of an undoped polysilicon layer or a doped polysilicon layer, i.e., a polysilicon layer having impurities, e.g., boron (B). Once the gate electrode 7 is formed, a spacer 9 made of an insulating material, e.g., silicon nitride, silicon oxide, and so forth, may be formed on the semiconductor substrate 1 and adjacent to sidewalls of the gate electrode 7. The spacer 9 may be in communication with the gate electrode 7.

Subsequently, as illustrated in FIGS. 2A-2B, the semiconductor substrate 1 and the gate electrode 7 may be anisotropically etched to form a substrate recess region 13a and a gate recess region 13b, respectively. In particular, the semiconductor substrate 1 and the gate electrode 7 may be etched so that at least one upper portion thereof, i.e., a portion including an upper surface of the semiconductor substrate 1 and the gate electrode 7, may be removed from the semiconductor substrate 1 and from the gate electrode 7, respectively, and unetched upper portions of the semiconductor substrate 1 and the gate electrode 7 may remain.

More specifically, when the substrate recess region 13a is formed, at least one substrate remaining portion 1a having an upper surface portion 1b, as illustrated in FIG. 2B, may remain between the substrate recess region 13a and the device isolating layer 3. The substrate remaining portion 1a may form a sidewall of the substrate recess region 13a and have a predetermined width, i.e., a horizontal distance as measured from an edge of the substrate recess region 13a to the device isolating layer 3, so that the device isolating layer 3 may be spaced from the recess region 13a. Similarly, at least one gate remaining portion 7a may remain between the gate recess region 13b and the spacer 9, as further illustrated in FIG. 2A, so that the gate remaining portion 7a may form a sidewall of the gate recess region 13b and have a predetermined width to separate the spacer 9 from the recess region 13b.

The substrate remaining portion 1a and the gate remaining portion 7a may extend upward with respect to the substrate and gate recess regions 13a and 13b, respectively, so that upper surfaces of the substrate remaining portion 1a and the gate remaining portion 7a may be at a same vertical level as an upper surface of the semiconductor substrate 1 and un upper surface of the spacer 9, respectively. It should be noted, however, that other recess region configurations, e.g., formation of only a substrate recess region 13a, formation of only a gate recess region 13b, and so forth, are not excluded from the scope of the present invention.

The anisotropic etching process of the semiconductor substrate 1 and the gate electrode 7 may be performed by using an etch gas in a predetermined direction, so that only predetermined portions of the upper surface of the semiconductor substrate 1 may be removed. In other words, during etching of the semiconductor substrate 1, the device isolating layer 3 and/or the spacer 9 may be shielded from etching to remain intact. In particular, during etching of the substrate recess region 13a, the etch gas may be directed along a direction forming a first angle θ1, e.g., an acute angle, with the sidewall 3c of the protrusion part 3b of the device isolating layer 3. The direction of the etch gas, i.e., the first angle θ1, may be adjusted with respect to a second angle θ2 formed between the sidewall 3c and the upper surface portion 1b of the substrate remaining portion 1a. For example, if the second angle θ2 is an acute angle, the direction of the etch gas may be adjusted, so that the etch gas may be incident on the upper surface of the semiconductor substrate 1 at a right angle.

The direction of the etch gas may also be adjusted with respect to a width T1, i.e., a distance as measured along a horizontal direction, of the upper surface portion 1b of the remaining substrate portion 1a. More specifically, calculation of an amount of silicon atoms potentially lost from the upper surface of the semiconductor substrate 1 during a cleaning process following the anisotropic etching and an amount of silicon atoms required to form a defect-free epitaxial layer may provide that a width T1 of the upper surface portion 1b may be at least about 50 angstroms.

The anisotropic etch process may include a first etch process to remove an oxide layer from the semiconductor substrate 1, i.e., a potential layer naturally formed on the upper surface of the semiconductor substrate 1 due to exposure to the atmosphere, and a second etch process to remove portions of the semiconductor substrate 1. The first etch process may be performed by supplying about 50-120 sccm of carbon tetrafluoride (CF4) gas. The first etch process may also include supplying source power of about 500-700 W and back-bias power of about 1-150 W for about 5-10 seconds under a temperature of about 20-60° C. and a pressure of about 5-10 mTorr. The first etch process may be performed without taking into consideration the first angle θ1. The second etch process may be performed by supplying about 300-700 sccm of hydrogen bromide (HBr) gas, about 100-500 sccm of helium (He) gas and about 5-15 sccm of oxygen (O₂) gas along the direction of the first angle θ1 as described previously. The second etch process may also include supplying a source power of about 300-500 W and back-bias power of about 1-100 W under a temperature of about 20-60° C. and a pressure of about 20-50 mTorr.

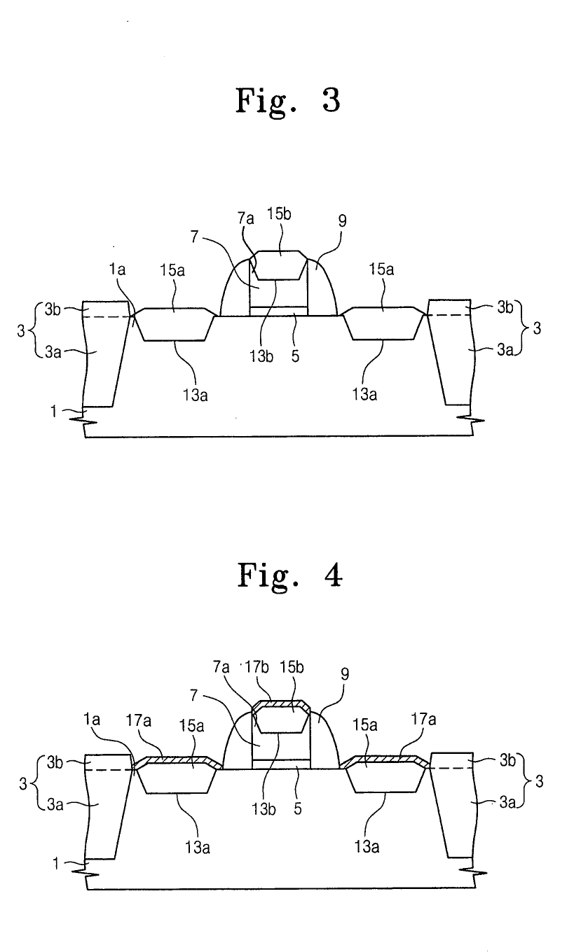

Once the anisotropic etching is complete, a substrate epitaxial layer 15a and a gate epitaxial layer 15b may be formed in the substrate recess region 13a and in the gate recess region 13b, respectively, as illustrated in FIG. 3, by a selective epitaxial growth method. In particular, the substrate and gate epitaxial layers 15a and 15b may be formed precisely in the substrate and gate recess regions 13a and 13b, respectively, so that no contact may exist between the substrate and gate epitaxial layers 15a and 15b and the device isolating layer 3 and the spacer 9, respectively, thereby providing defect-free epitaxial layers. For example, the substrate epitaxial layer 15a may be spaced apart from the device isolating layer 3 by the width T1 of the surface of the upper surface portion 1b of the substrate remaining portion 1a. Formation of the substrate and gate epitaxial layers 15a and 15b apart from the device isolating layer 3 and the spacer 9, respectively, may be advantageous to facilitate metallic silicide layer formation, as will be discussed in detail below with respect to FIG. 4.

The substrate and gate epitaxial layers 15a and 15b may be formed of silicon-germanium, while a ratio of silicon to germanium may be varied with respect to a desired form and thickness of the substrate and gate epitaxial layers 15a and 15b. The substrate and gate epitaxial layers 15a and 15b may be doped with impurities, e.g., boron (B), in-situ. Alternatively, for example, after formation of the substrate and gate epitaxial layers 15a and 15b is complete, P-type impurities may be injected into the substrate and gate epitaxial layers 15a and 15b, followed by annealing. The substrate and gate epitaxial layers 15a and 15b may be formed so that upper surfaces thereof may be higher with respect to a vertical distance as compared to the upper surface of the semiconductor surface 1, i.e., the substrate and gate epitaxial layers 15a and 15b may protrude upward from the substrate and gate recess regions 13a and 13b with respect to the upper surface of the semiconductor substrate 1.

Next, as illustrated in FIG. 4, a metallic layer (not shown) may be deposited and annealed on the semiconductor substrate 1. In particular, the metallic layer may coat upper surfaces of the semiconductor substrate 1, device isolating layer 3, spacer 9, substrate epitaxial layers 15a, and gate epitaxial layers 15b. The metallic layer may interact with the substrate and gate epitaxial layers 15a and 15b to form metallic silicide layers 17a and 17b, respectively, on upper surfaces of the substrate and gate epitaxial layers 15a and 15b, as illustrated in FIG. 4. The metallic layer does not interact with the device isolating layer 3 or the spacer 9 and, therefore, the metallic layer may be removed from the surfaces of the device isolating layer 3 and the spacer 9 without modification thereof.

Accordingly, as illustrated in FIG. 4, formation of metallic silicide layers 17a and 17b may be controlled, so that the metallic silicide layers 17a and 17b may be formed only on surfaces of the substrate and gate epitaxial layers 15a and 15b, respectively. Growth of the substrate and gate epitaxial layers 15a and 15b apart from the device isolating layer 3 and the spacer 9, respectively, may facilitate formation of the metallic silicide layers 17a and 17b in close proximity to the device isolating layer 3 and the spacer 9, respectively, so that gaps or voids between the metallic silicide layers 17a and 17b and the device isolation layer 3 and the spacer 9, respectively, may be eliminated, thereby minimizing junction leakage current.

For example, the epitaxial layers 15a and 15b and the gate electrode 7 may be doped with P-type impurities to form a PMOS semiconductor device having the substrate epitaxial layer 15a as a source/drain layer. Formation of the epitaxial layers 15a and 15b according to an embodiment of the present invention may generate strain in a channel region of the gate electrode 7, thereby increasing carrier mobility and overall operation speed of the PMOS. Further, formation of the substrate epitaxial layer 15a above the upper surface of the semiconductor substrate 1, may facilitate separation of the metallic silicide layers 17a and 17b from a boundary portion between source/drain and well regions. Therefore, a potential junction leakage current in the boundary portion may be minimized as compared to conventional semiconductors devices.

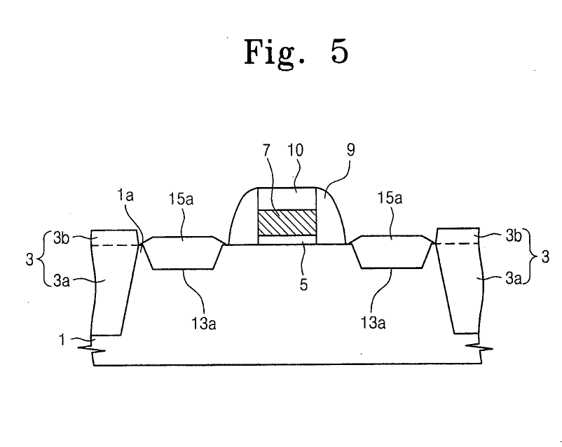

According to another embodiment of the present invention illustrated in FIG. 5, a semiconductor device may be formed in a similar manner to the semiconductor device described previously with respect to FIGS. 1-4, with the exception that a capping layer pattern 10 may be formed on the gate electrode 7. Accordingly, the spacer 9 may be in communication with the capping layer pattern 10, the gate electrode 7 and the gate insulating layer 5. Further, the gate electrode 7 may not be etched because it may be covered with the capping layer pattern 10. The semiconductor substrate 1 may be anisotropically etched to form a substrate recess region 13a as previously described with respect to FIGS. 1-4 and, therefore, a detailed description of procedures and conditions for etching and formation of the metal silicide layers will not be repeated herein.

The method of forming a semiconductor device according to an embodiment of the present invention may be advantageous in providing recess regions in a semiconductor substrate spaced apart from the device isolating layer and/or spacer. As a result, control of epitaxial layers growth in the recess regions may be improved to avoid any silicide layer formation along the device isolating layer and/or spacer, thereby minimizing junction leakage current.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming a semiconductor device, comprising:
forming a device isolating layer having a depression part and a protrusion part in a semiconductor substrate;
forming a gate insulating layer and a gate electrode on the semiconductor substrate;
forming a spacer in communication with the gate electrode;
removing a portion of the semiconductor substrate to form at least one substrate recess region in an upper surface of the semiconductor substrate and at least one substrate remaining portion extending to a same height as the semiconductor substrate, so that the substrate remaining portion forms a sidewall of the substrate recess region and is in communication with the device isolating layer; and
forming a substrate epitaxial layer in the substrate recess region.

2. The method as claimed in claim 1, wherein forming the substrate remaining portion includes performing anisotropic dry etching process.

3. The method as claimed in claim 2, wherein performing the anisotropic dry etching process includes directing an etch gas in a direction forming a first angle with a sidewall of the protrusion part of the device isolating layer.

4. The method as claimed in claim 3, wherein forming the first angle with a sidewall of the protrusion part of the device isolating layer includes forming an acute angle.

5. The method as claimed in claim 3, wherein an upper surface of the substrate remaining portion is formed to have a width of at least about 50 angstroms.

6. The method as claimed in claim 1, wherein forming the substrate remaining portion includes performing an etch process by supplying about 300-700 sccm of hydrogen bromide (HBr) gas, about 100-500 sccm of helium (He) gas and about 5-15 sccm of O₂ gas, with a source power of about 300-500 W and back-bias power of about 1-100 W, under a temperature of about 20-60° C. and a pressure of about 20-50 mTorr.

7. The method as claimed in claim 6, wherein forming the substrate remaining portion further comprises removing an oxide layer before etching by supplying about 50-120 sccm of carbon tetrafluoride (CF₄) gas, and supplying source power of about 500-700 W with a back-bias power of about 1-150 W for about 5-10 seconds, under a temperature of about 20-60° C. and a pressure of about 5-10 mTorr.

8. The method as claimed in claim 2, wherein forming the substrate epitaxial layer includes forming a silicon germanium epitaxial layer.

9. The method as claimed in claim 1, further comprising forming a metal silicide layer on the substrate epitaxial layer.

10. The method as claimed in claim 2, further comprising:
removing a portion of the gate electrode to form at least one gate recess region and a gate remaining portion; and
forming a gate epitaxial layer in the gate recess region.

11. The method as claimed in claim 10, wherein forming the gate epitaxial layer includes forming a silicon germanium epitaxial layer.

12. The method as claimed in claim 1, further comprising forming a capping layer pattern on the gate electrode.

13. The method as claimed in claim 1, wherein forming the substrate remaining portion comprises:
forming a mask pattern on the device isolating layer and the semiconductor substrate adjacent to the device isolating layer;
anisotropically etching the semiconductor substrate by using the mask pattern as etch mask; and
removing the mask pattern.

14. A semiconductor device, comprising:
a semiconductor substrate;
a device isolating layer on the semiconductor substrate, the device isolating layer including a depression part in the semiconductor substrate and a protrusion part projecting upward from the semiconductor substrate;
a gate electrode on the semiconductor substrate;
a spacer on the semiconductor substrate and in communication with the gate electrode;
at least one substrate recess region in the semiconductor substrate;
a substrate remaining portion in communication with the device isolating layer and the substrate recess region, the substrate remaining portion having a substantially same height level as an upper surface of the semiconductor substrate; and
a substrate epitaxial layer in the substrate recess region.

15. The semiconductor device as claimed in claim 14, wherein an upper surface of the substrate remaining portion has a width of at least about 50 angstroms.

16. The semiconductor device as claimed in claim 14, further comprising:
at least one gate recess region in the gate electrode;
a gate remaining portion in communication with the spacer; and
a gate epitaxial layer in the gate recess region.

17. The semiconductor device as claimed in claim 14, wherein the substrate epitaxial layer includes a silicon germanium epitaxial layer.

18. The semiconductor device as claimed in claim 16, wherein the substrate epitaxial layer and the gate epitaxial layer include a silicon germanium epitaxial layer.

19. The semiconductor device as claimed in claim 14, further comprising a capping layer pattern on the gate electrode.

20. The semiconductor device as claimed in claim 14, further comprising a silicide metal layer on the epitaxial layer.
